(19) United States
(12) Patent Application Publication
(10) Pub. No.: US 2024/0077919 A1
(43) Pub. Date: Mar. 7, 2024

(54) TANDEM MODULATION DEVICE FAN AND CONTROL METHOD THEREOF

(71) Applicant: SHUOQI ELECTRONIC HEAT DISSIPATION TECHNOLOGY (DONGGUAN) CO., LTD., GUANGDONG (CN)

(72) Inventors: Tianhe XIE, GUANGDONG (CN); Hongbing XIE, GUANGDONG (CN); Difa XIAO, GUANGDONG (CN)

(21) Appl. No.: 17/981,498

(22) Filed: Nov. 7, 2022

(30) Foreign Application Priority Data
Sep. 2, 2022 (CN) 202211072656.5

(51) Int. Cl. G06F 1/20; G05B 15/02

(52) U.S. Cl. CPC G06F 1/20; G05B 15/02

(57) ABSTRACT

Disclosed are a tandem modulation device fan and a control method thereof. The tandem modulation device fan comprises a frame, fan blades disposed in the frame, and a light-emitting module disposed in the frame. Two corresponding sides of the frame are each provided with a circuit board and a pin structure. Pins and the circuit boards on the two sides can automatically switch and recognize inputs and outputs irrespective of the polarity. The two sides, provided with the circuit boards, of the frame are each provided with a magnet for magnetic connection with the frame of an adjacent fan. The circuit board is electrically connected to a master controller. Fans are connected end-to-end through attraction of magnets, such that the electrical conductivity is improved, and the service life is prolonged.

### BACKGROUND OF THE INVENTION

The invention relates to a fan, in particular to a tandem modulation device fan and a control method thereof.

Signals for power supply of radiator fans and RGB LED atmosphere lights of computer case systems on the present market are controlled separately, and adjacent fans with RGB LEDs are bound together through two groups of wires, thus bringing inconvenience to manufacturers and terminal users and causing ambiguities and making it difficult to sort wires. For example, due to the fact that signals are controlled independently in the prior art, when multiple fans are connected, these fans should be connected in a correct direction and should be aligned and then slid relatively to be clamped in place, which may cause abrasion of the contacts of electrical appliances, compromising the electrical conductivity and shortening the service life.

### BRIEF SUMMARY OF THE INVENTION

The objective of the invention is to solve the aforesaid technical problems by providing a tandem modulation device fan and a control method thereof, which can save space, make assembly easier and reduce material costs.

To fulfill the above objective, the invention adopts the following technical solution:
A tandem modulation device fan comprises a frame, and fan blades disposed in the frame;
The tandem modulation device fan further comprises a light-emitting module disposed in the frame;
Two corresponding sides of the frame are each provided with a circuit board and a pin structure disposed above the circuit board;
The two sides, provided with the circuit boards, of the frame are each provided with a magnet for magnetic connection with the frame of an adjacent fan;
The circuit board is electrically connected to a master controller.

As a preferred embodiment of the invention, the frame comprises a frame top cover and a frame bottom cover, and the frame top cover and the frame bottom cover are fixedly connected through screws or in a buckled manner.

As a preferred embodiment of the invention, the polarity of the magnets on the frame is opposite to that of the magnets on the frame of the adjacent fan, and the adjacent fans are connected through attraction of the magnets.

As a preferred embodiment of the invention, the frame is square structure with four sides which are symmetrically divided into two groups, the two sides in one group are each provided with one circuit board and one pin structure, and the two sides in the other group are each provided with a side trim panel.

As a preferred embodiment of the invention, four pads are disposed on side faces of the frame.

As a preferred embodiment of the invention, the circuit board comprises a slave fan MCU and address code module, a fan motor and driver module, a strip module and a DC stabilizer module, and the slave fan MCU and address code module is electrically connected to the fan motor and driver module, the strip module and the DC stabilizer module.

As a preferred embodiment of the invention, a fan blade circular-framed trim panel is disposed on an outer side of the fan motor and driver module.

As a preferred embodiment of the invention, the master controller of the device fan comprises a PC power supply module, a PC App USB port, a master controller MCU and output ports, and the output ports are in communication connection with the circuit boards.

A control method of the tandem modulation device fan comprises:
Forming a fan system by the master controller and multiple slave device fans;
Enabling the master controller to communicate with and recognize the multiple slave device fans based on a UART protocol or an I2C protocol; if the slave device fans are recognized by the master controller, performing data transfer through all ports according to a communication protocol; if the slave device fans fail to be recognized by the master controller, determining the slave device fans as common fans, and defining PWM signal output and rotational speed signal input functions by the ports based on the UART protocol or the I2C protocol to support function control of the common fans; and
Enabling the master controller to communicate with a PC App through the USB port to perform control on the slave device fans or the common fans, wherein the control comprises a signal control process of the master controller and a signal control process of the salve device fans;
The signal control process of the master controller comprises:
Step S101: cascading and integrating signals of the master controller, the fans, and RGB LED lights of the light-emitting modules, enabling the master controller to communicate with and control the slave device fans based on the UART protocol or the I2C protocol, customizing six groups of output ports or setting the output ports as required, and controlling each group of signals independently;
Step S102: enabling the master controller to communicate with a PC through the USB port, and controlling, by a user, rotational speeds and light effects of the slave device fans at an output end through a PC App; and
Step S103: recognizing, by the master controller, whether a fan is a slave device fan or a common PWM signal-controlled fan based on the UART protocol or the I2C protocol to perform signal switching, so as to adapt to the common PWM signal-controlled fan;
The signal control process of the slave device fans comprises:
Step S201: enabling the slave device fans to recognize each other based on the UART protocol or the I2C protocol, and automatically generating an address code; automatically numbering the fan connected to the master controller as a first slave device fan and numbering the fan connected to the first slave device fan as a second slave device fan to cascade four fans by analogy or set the fans as required; and
Step S202: setting an MCU for each slave device fan to realize communication with the master controller, setting input ports and output ports through which all the cascaded slave device fans receive instructions from the master controller and send relevant data back to the master controller, and sending, by the master controller, data to the PC App to be processed;
Each slave device fan is recognized and controlled as an individual specifically through the following steps:
Independently setting and controlling rotational speeds and data reading of the four cascaded fans in each group, as well as effects of the light-emitting modules, wherein the light effects of the light-emitting modules are set to be in different colors separately;
Providing all data to the master controller based on the UART protocol or the I2C protocol, and then sending the data to the PC App to be managed based on a USB protocol, wherein all control instructions are sent to the controller by the PC App and are then transmitted to the slave device fans.

Compared with the prior art, the tandem modulation device fan and the control method thereof have the following beneficial effects:
1. Control signals of radiation fans and RGB LED atmosphere lights of a computer case system are cascaded and combined to be transmitted;
2. Slave fans (SLAVE) can be controlled independently, and on an App of a PC, corresponding rotational speeds and light effects of slave fans (SLAE) on different channels are set by the master controller (MASTER);
3. Input signals and output signals are switched through physical encoding of contacts or through chip analog switches, such that input and output ports are shared by fans irrespective of the direction, and incorrect plugging or reversed plugging is avoided;
4. By combining signal lines, a group of signal and power supply lines can be omitted, such that lines can be sorted more easily when multiple fans are connected, the number of output ports, for the RGB LED lights, of the controller is reduced, a control box can be simpler, and the cost is reduced;
5. Magnets are used for connecting fans, such that the fans can be connected directly through attraction of the magnets, and users can connect the fans more easily.

### BRIEF DESCRIPTION OF THE DRAWINGS

FIG. 1 is an overall structural view of the invention;

FIG. 2 is a schematic diagram of a specific embodiment of the invention;

FIG. 3 is a structural view of a master controller according to the invention;

FIG. 4 is a connection diagram of a slave device fan 1 # and a master controller according to the invention;

FIG. 5 is a schematic diagram of a slave device fan 2 # and tandem connection thereof according to the invention;

FIG. 6 is a schematic diagram of a slave device fan 3 # and tandem connection thereof according to the invention;

FIG. 7 is a schematic diagram of a slave device fan 4 # and tandem connection thereof according to the invention;

FIG. 8 is a schematic diagram of a circuit board and a pin structure according to the invention;

FIG. 9 is a structural diagram of a fan system according to the invention.

In the figures: 1, frame; 11, frame top cover; 12, frame bottom cover; 13, side trim panel; 14, pad; 2, fan blade; 21, fan blade circular-framed trim panel; 3, magnet; 31, N-pole magnet; 32, S-pole magnet; 4, light-emitting module; 5, circuit board; 51, slave fan MCU and address code module; 52, fan motor and driver module; 53, strip module; 54, DC stabilizer module; 6, pin structure; 7, master control panel; 71, PC power supply module; 72, PC App USB port; 73, master controller MCU; 74, output port.

### DETAILED DESCRIPTION OF THE INVENTION

The technical solutions of the embodiments of the invention will be clearly and completely described below in conjunction with the drawings of these embodiments. Obviously, the embodiments in the following description are merely illustrative ones, and are not all possible ones of the invention.

It should be understood that, in the description of the invention, the terms such as “upper”, “lower”, “front”, “back”, “left”, “right”, “top”, “bottom”, “inner” and “outer” are used to indicate directional or positional relationships based on the accompanying drawings merely for the purpose of facilitating and simplifying the description of the invention, do not indicate that a device or element referred to must be in a specific direction, or configured and operated in a specific direction, and thus, should not be understood as limitations of the invention.

### Embodiment 1

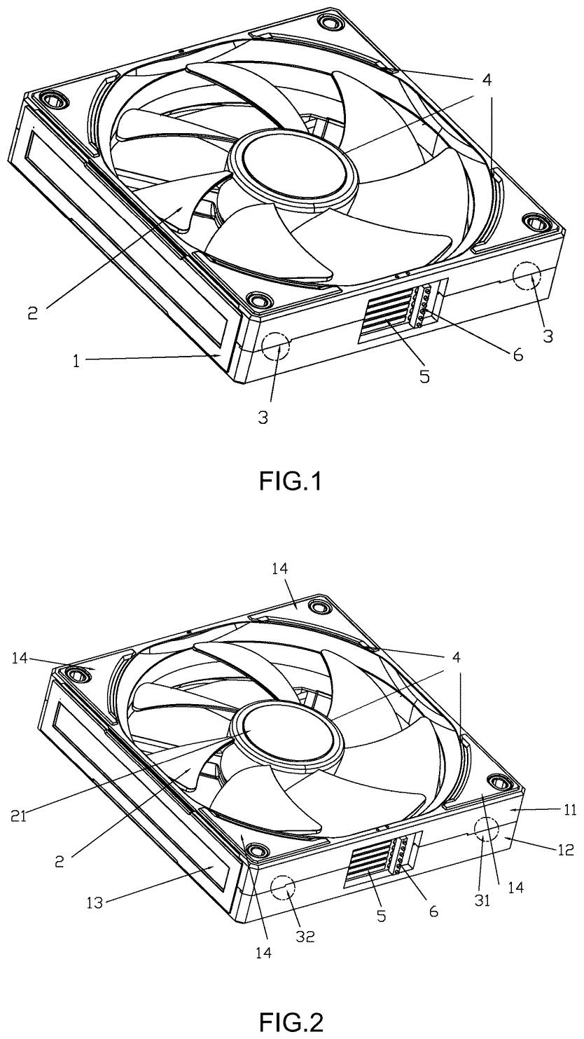

As shown in FIG. 1 and FIG. 2, a tandem modulation device fan comprises a frame 1 and fan blades 2 disposed in the frame 1, and further comprises a light-emitting module 4 disposed in the frame 1. In the invention, the frame is arranged according to user requirements, and the frame may be formed integrally, or be provided with a top cover and a bottom cover which are of a separated structure. The light-emitting module 4 is a RGB LED light, and may be disposed at different positions of the frame or the fan blades. For example, RGB LED lights are regularly distributed on the inner side of the frame and the periphery of the fan blades, or on a fan motor and driver module in the middle of the fan blades, such that light can be emitted at multiple positions to fulfill a dazzling effect. Of course, the light-emitting module 4 is arranged according to user requirements, the position of the light-emitting module 4 is not fixed, and both the position and the shape of the light-emitting module 4 are set as required.

As shown in FIG. 1 and FIG. 2, the frame 1 comprises a frame top cover 11 and a frame bottom cover 12, wherein the frame top cover 11 and the frame bottom cover 12 are fixedly connected through screws or in a buckled manner. In the figures, the frame top cover 11 and the frame bottom cover 12 are fixedly connected through screws, but the invention is not limited to screw connection. For example, buckle structures may be disposed on the frame top cover 11 and the frame bottom cover 12, and the frame top cover 11 and the frame bottom cover 12 are connected in a buckled manner, which also falls within the protection scope of the invention. The fan blades are regularly distributed in the frame and are installed on a fan motor and driver module, and the fan motor and driver module is a drive motor (not shown); as shown in FIG. 2, the drive motor is disposed below a fan blade circular-framed trim panel 21 of the fan blades, which is not shown; the drive motor is electrically connected to a fan motor and driver module 52 and is driven by the fan motor and driver module 52 to work to drive the fan blades to rotate.

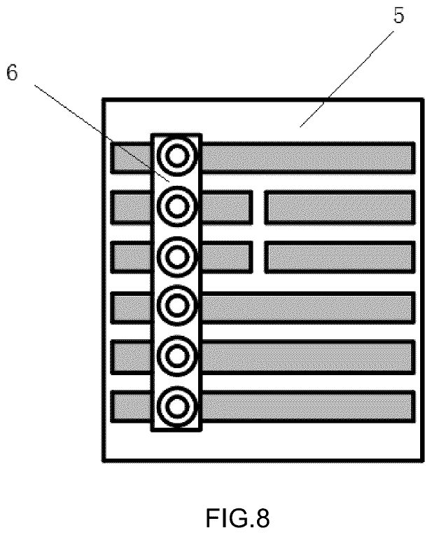

As shown in FIG. 1, FIG. 2 and FIG. 8, two corresponding sides of the frame 1 are each provided with a circuit board 5 and a pin structure 6, wherein the pin structure 6 is disposed above the circuit board 5 and is electrically connected to the circuit board 5, and the pin structure 6 is a pogo pin structure. In the prior art, two sets of male and female terminals are used to realize connection. In the invention, multiple slave device fans are electrically connected through pogo pins and contacts, such that abrasion and friction can be reduced, thus improving the electrical conductivity and prolonging the service life.

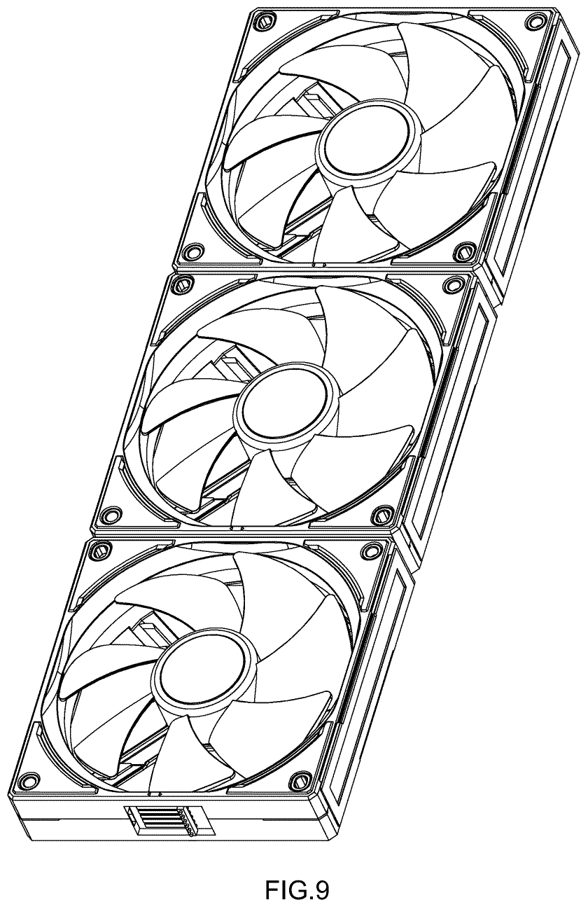

To realize better connection of the pin structures 6, as shown in FIG. 1, FIG. 2 and FIG. 9, the two sides, provided with the circuit boards 5, of the frame 1 are each provided with a magnet 3 for magnetic connection with the frame of an adjacent fan. In the invention, the polarity of the magnets on the frame 1 is opposite to that of the magnets 3 on the frame of the adjacent fan, and the adjacent fans are connected by attraction of the magnets. As shown in FIG. 9, three adjacent fans are connected through attraction of the magnets and are then fixed on a case with screws. As shown in FIG. 2, 31 represents an N-pole magnet, and 32 represents an S-pole magnet; when the fan is connected to an adjacent fan, the magnet adjacent to the N-pole magnet 31 is an S-pole magnet, the magnet corresponding to the S-pole magnet 32 is an N-pole magnet, and by analogy, multiple adjacent device fans are connected through attraction of the magnets. In the invention, the fans are connected based on the principle of attraction of the S pole and the N pole of magnets, which also accords with the use characteristics of pogo pins; and when assembled, the fans can be attracted together directly to be connected, such that abrasion and friction can be reduced, thus improving the electrical conductivity and prolonging the service life.

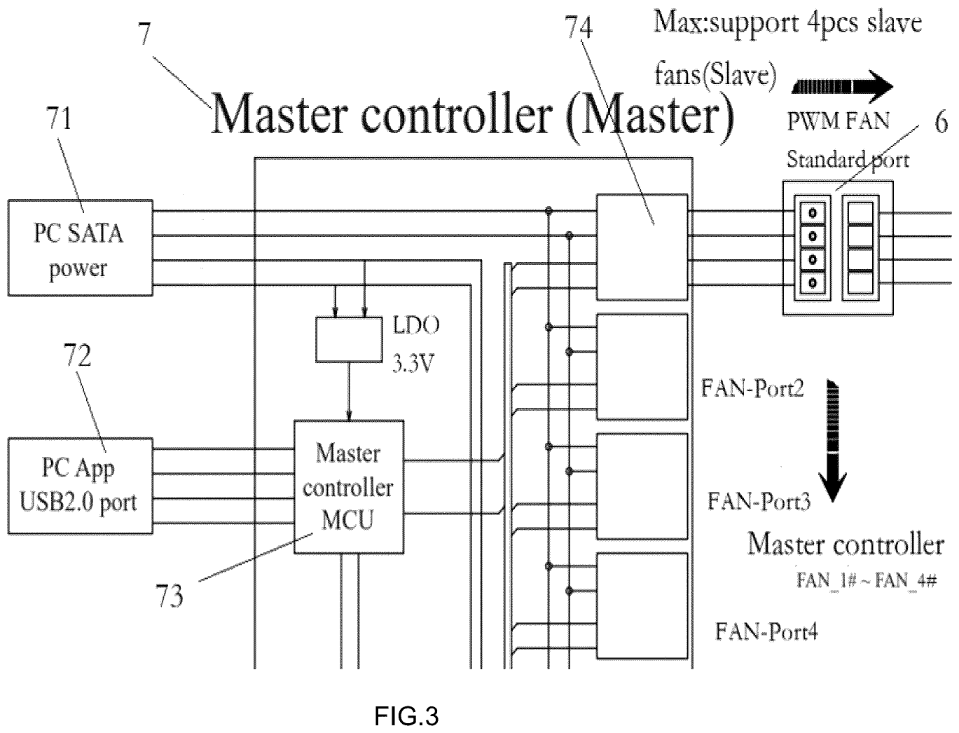

As shown in FIG. 3, in the invention, the circuit board 5 is electrically connected to a master controller 7, such that slave device fans can be separately controlled by the master controller 7.

As shown in FIG. 1 and FIG. 2, the frame 1 is a square structure with four sides which are symmetrically divided into two groups, the two sides in one group are each provided with one circuit board 5 and one pin structure 6, and the two sides in the other one of the symmetrical structures are each provided with a side trim panel 13. In the invention, the side trim panels 13 may be adopted, or side panels may be used. Four pads 14 are disposed on side faces of the frame 1 to fulfill an anti-vibration and anti-slid effect. A fan blade circular-framed trim panel 21 is disposed on the outer side of the fan motor and driver module 52. Here, the fan blade circular-framed trim panel 21 is arranged as required, and may be not arranged in some fans. The side trim panels 13 and the fan blade circular-framed trim panel 21 are made of mylar, alloy materials, or other decorative or insulative materials.

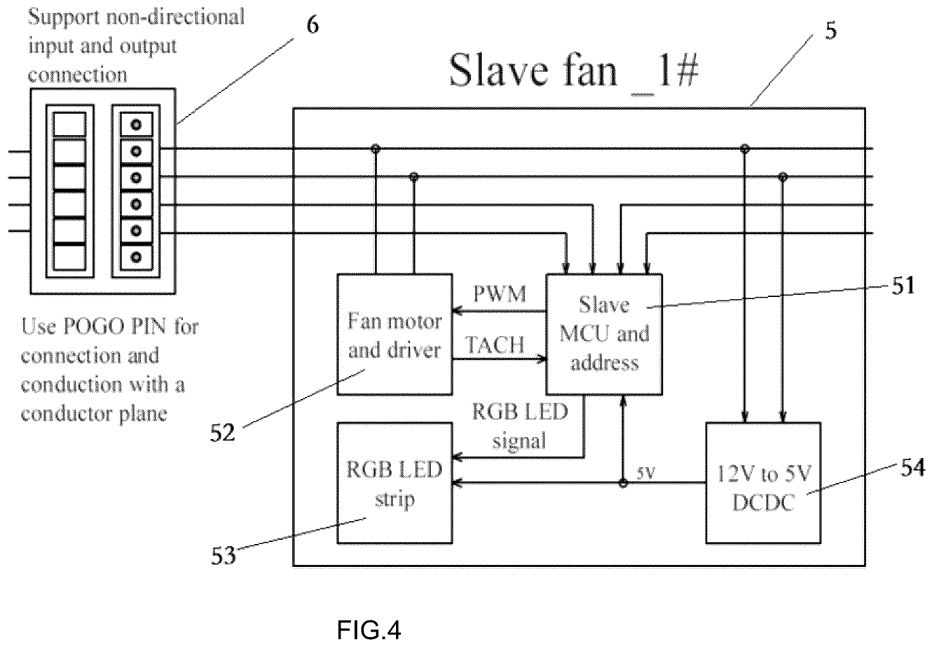

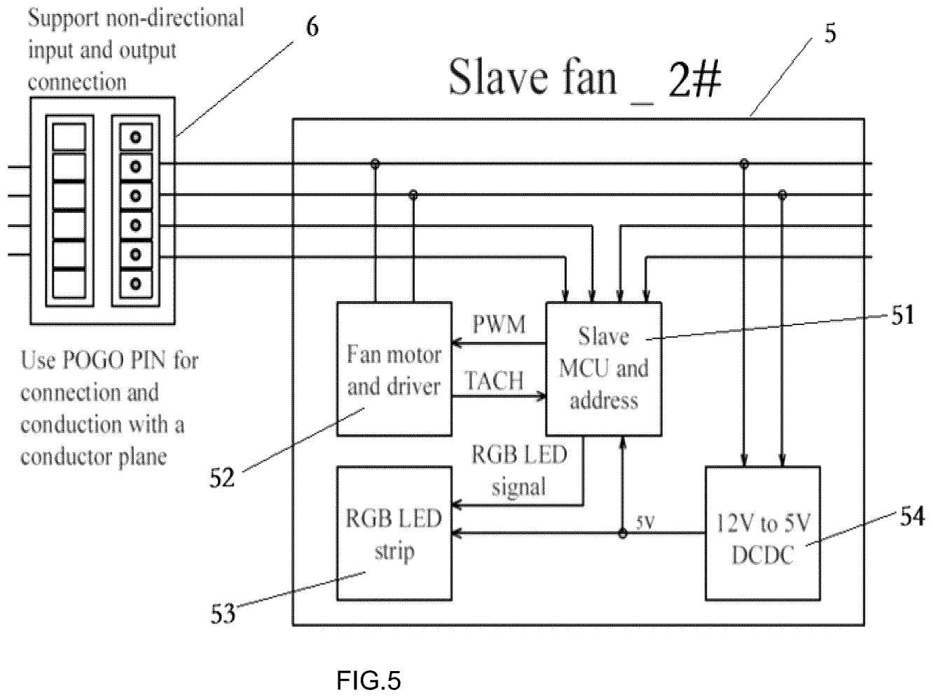

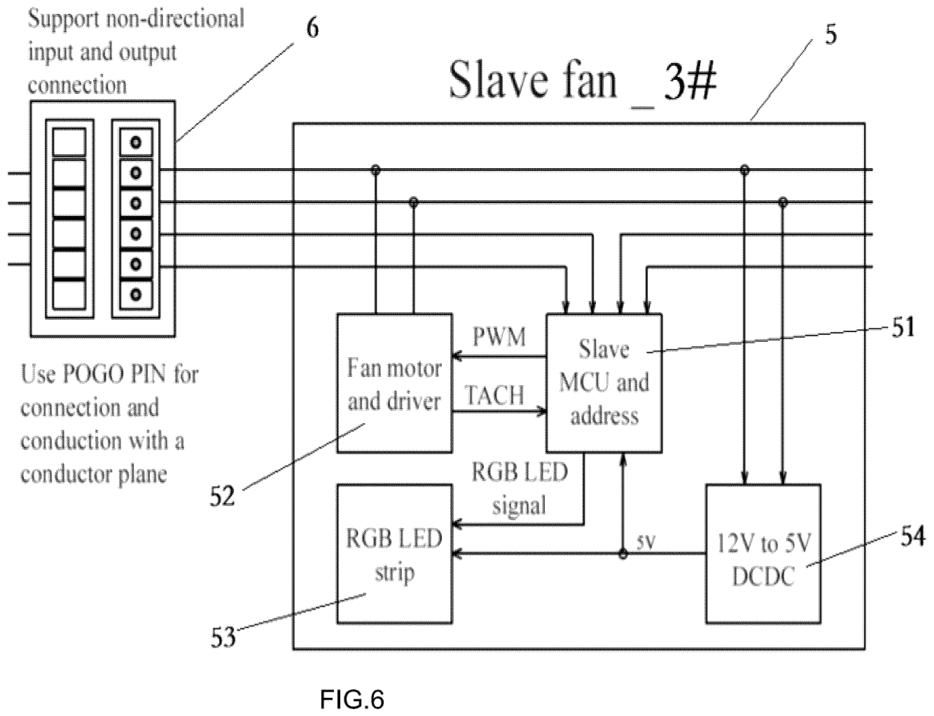

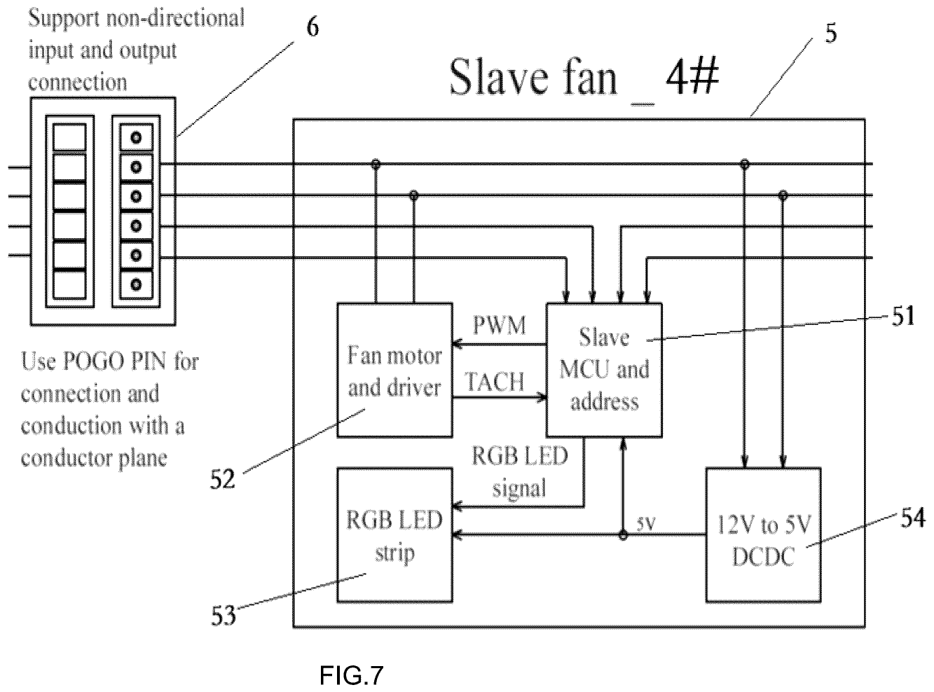

As shown in FIG. 4-FIG. 8, the circuit board 5 comprises a slave fan MCU and address code module 51, a fan motor and driver module 52, a strip module 53 and a DC stabilizer module 54, wherein the slave fan MCU and address code module 51 is electrically connected to the fan motor and driver module 52, the strip module 53 and the DC stabilizer module 54. The slave fan MCU and address code module 51 of the salve device fan performs recognition based on a UART protocol or an I2C protocol, generates an address code automatically, is connected to the master controller 7 (Master), and then sends a drive signal to the fan motor and driver module to drive the drive motor of the device fan to drive the fan blades to work and also sends a drive signal to the strip module to drive the strip module to work, and the 12V-to-5V DC stabilizer module 54 can ensure the operation of the salve device fan. The master controller provides stable power for the slave device fans. In the invention, the master controller 7 controls the slave device fans independently, and can separately control the rotational speed of the slave device fans and the strobe color of the LED lights.

As shown in FIG. 3, the master controller 7 of the device fan comprises a PC power supply module 71, a PC App USB port 72, a master controller MCU 73 and output ports 74, wherein the output ports 74 are in communication connection with the circuit boards 5.

A control method of the tandem modulation device fan comprises:
A fan system is formed by the master controller and multiple slave device fans;
The master controller communicates with and recognizes the multiple slave device fans based on a UART protocol or an I2C protocol; if the slave device fans are recognized by the master controller, data transfer is performed through all ports according to a communication protocol; if the slave device fans fail to be recognized by the master controller, the slave device fans as are determined as common fans, and PWM signal output and rotational speed (TACH) signal input functions are defined by the ports based on the UART protocol or the I2C protocol to support function control of the common fans; and
The master controller communicates with a PC App through the USB port to perform control on the slave device fans or the common fans, wherein the control comprises a signal control process of the master controller and a signal control process of the salve device fans;
The signal control process of the master controller comprises:
Step S101: signals of the master controller, the fans and the LED lights of the light-emitting modules are integrated, the master controller communicates with and controls the slave device fans based on the UART protocol or the I2C protocol, six groups of output ports are set or the output ports are set as required, and each group of signals is controlled independently;
Step S102: the master controller communicates with a PC through the USB port, and a user controls rotational speeds and light effects of the slave device fans at an output end through a PC App;
Step S103: the master controller recognizes whether a fan is a slave device fan or a common PWM signal-controlled fan based on the UART protocol or the I2C protocol to perform signal switching, so as to adapt to the common PWM signal-controlled fan;
The signal control process of the slave device fans comprises:
Step S201: the slave device fans recognize each other based on the UART protocol or the I2C protocol, and automatically generate an address code; the fan connected to the master controller is automatically numbered as a first slave device fan, the fan connected to the first slave device fan is numbered as a second slave device fan, and by analogy, four fans are cascaded or the fans are set as required; and
Step S202: an MCU is set for each slave device fan to realize communication with the master controller, input ports and output ports, through which all the cascaded slave device fans receive instructions from the master controller and send relevant data back to the master controller, are set, and data is sent to the PC App by the master controller, so as to be processed.

Further, as shown in FIG. 3, the specific signal process of the master controller (Master) is as follows:

Signals of the master controller (Master), the fans and the LED lights (ARGB LEDs) are integrated, the master controller communicates with and controls the slave device fans (SLAVE DEVICE) based on the UART protocol or the I2C protocol, six groups of output ports are set (as shown in FIG. 3, six groups of output ports 74 are set), each group of output ports can control four slave device fans, and each group of signals is controlled independently;

The master controller (Master) communicates with a PC through the USB port, and a user controls rotational speeds and light effects of the slave device fans (SLAVE DEVICE) at an output end through a PC App;

The master controller (Master) can recognize whether a fan is the slave device fan (SLAVE DEVICE) or a common PWM signal-controlled fan based on the UART protocol or the I2C protocol to perform signal switching, so as to adapt to control of the common PWM signal-controlled fan;

Fan port connectors of the master controller (Master) are standard four-pin eccentric pin holders for computer mainboards, and are compatible with the common PWM signal-controlled fan.

As shown in FIG. 4-FIG. 9, the specific signal process of the slave device fans (SLAVE DEVICE) is as follows:
The slave device fans (SLAVE DEVICE) recognize each other based on the UART protocol or the I2C protocol, and automatically generate an address code; the fan connected to the master controller (Master) is automatically numbered as a first slave device fan, the fan connected to the first slave device fan (SLAVE DEVICE) is numbered as a second slave device fan, and by analogy, four fans are cascaded; the invention is not limited to or the fans are set as required; and
An MCU is set for each slave device fan (SLAVE DEVICE) to realize communication with the master controller (Master), input ports and output ports, through which all the cascaded slave device fans receive instructions from the master controller (Master) and send relevant data back to the master controller, are set, and data is sent to the PC App by the master controller (Master), so as to be processed.

As shown in FIG. 4-FIG. 9, each slave device fan (SLAVE DEVICE) is recognized and controlled as an individual specifically through the following steps:
Rotational speeds and data reading of the four cascaded fans in each group, as well as effects of the LED lights are set and controlled independently, for example, the rotational speed of the first fan is set to 1500 RPM, the rotational speed of the second fan is set to 1000 RPM, the third fan is stopped, and the rotational speed of the fourth fan is set to 2000 RPM; the effect of the LED lights are set are separately set to be in different colors, for example, as shown in FIG. 3-FIG. 9, a first port of the master controller outputs for control pins: DC12V, GND, UART-IN_1 and UART-IN_2, to independently control the salve fan_1 #, the slave fan_2 #, the slave fan_3 # and the slave fan_4 #, which are then separately controlled based on the UART protocol or the I2C protocol;
All data is provided to the master controller (Master) based on the UART protocol or the I2C protocol, and then sent to the PC App to be managed based on a USB protocol, wherein all control instructions are sent to the controller (Master) by the PC App and are then transmitted to the slave device fans (SLAVE DEVICE).

By combining signal lines, a group of signal and power supply lines can be omitted, such that lines can be sorted more easily when multiple fans are connected, the number of output ports, for the RGB LED lights, of the controller is reduced, a control box can be simpler, and the cost is reduced; and when assembled, fans are attracted together by magnets and are connected through POGP PINs, irrespective of the direction of input and output ports,

The foregoing are merely preferred specific implementations of the invention, and the protection scope of the invention is not to the above description. All equivalent substitutions or changes made by any skilled in the art within the technical scope disclosed by the invention according to the technical solution of the invention should fall within the protection scope of the invention.

What is claimed is:

1. A tandem modulation device fan, comprising a frame (1), and fan blades (2) disposed in the frame (1), wherein:
the tandem modulation device fan further comprises a light-emitting module (4) disposed in the frame (1);
two corresponding sides of the frame (1) are each provided with a circuit board (5) and a pin structure (6) disposed above the circuit board (5);
the two sides, provided with the circuit boards (5), of the frame (1) are each provided with a magnet (3) for magnetic connection with the frame of an adjacent fan;
the circuit board (5) is electrically connected to a master controller (7).

2. The tandem modulation device fan according to claim 1, wherein the frame (1) comprises a frame top cover (11) and a frame bottom cover (12), and the frame top cover (11) and the frame bottom cover (12) are fixedly connected through screws or in a buckled manner.

3. The tandem modulation device fan according to claim 1, wherein a polarity of the magnets on the frame (1) is opposite to that of the magnets (3) on the frame of the adjacent fan, and the adjacent fans are connected through attraction of the magnets.

4. The tandem modulation device fan according to claim 1, wherein the frame (1) is square structure with four sides which are symmetrically divided into two groups, the two sides in one group are each provided with one said circuit board (5) and one said pin structure (6), and the two sides in the other group are each provided with a side trim panel (13).

5. The tandem modulation device fan according to claim 4, wherein our pads (14) are disposed on side faces of the frame (1).

6. The tandem modulation device fan according to claim 1, wherein the circuit board (5) comprises a slave fan MCU and address code module (51), a fan motor and driver module (52), a strip module (53) and a DC stabilizer module (54), and the slave fan MCU and address code module (51) is electrically connected to the fan motor and driver module (52), the strip module (53) and the DC stabilizer module (54).

7. The tandem modulation device fan according to claim 6, wherein a fan blade circular-framed trim panel (21) is disposed on an outer side of the fan motor and driver module (52).

8. The tandem modulation device fan according to claim 1, wherein the master controller (7) comprises a PC power supply module (71), a PC App USB port (72), a master controller MCU (73) and output ports (74), and the output ports (74) are in communication connection with the circuit boards (5).

9. A control method of a tandem modulation device fan, comprising:
forming a fan system by a master controller and multiple slave device fans;
enabling the master controller to communicate with and recognize the multiple slave device fans based on a UART protocol or an I2C protocol; if the slave device fans are recognized by the master controller, performing data transfer through all ports according to a communication protocol; if the slave device fans fail to be recognized by the master controller, determining the slave device fans as common fans, and defining PWM signal output and rotational speed signal input functions by the ports based on the UART protocol or the I2C protocol to support function control of the common fans; and
enabling the master controller to communicate with a PC App through a USB port to perform control on the slave device fans or the common fans, wherein the control comprises a signal control process of the master controller and a signal control process of the salve device fans;
the signal control process of the master controller comprises:
Step S101: cascading and integrating signals of the master controller, the fans, and RGB LED lights of light-emitting modules, enabling the master controller to communicate with and control the slave device fans based on the UART protocol or the I2C protocol, customizing six groups of output ports or setting the output ports as required, and controlling each group of signals independently;
Step S102: enabling the master controller to communicate with a PC through a USB port, and controlling, by a user, rotational speeds and light effects of the slave device fans at an output end through a PC App; and
Step S103: recognizing, by the master controller, whether a fan is a slave device fan or a common PWM signal-controlled fan based on the UART protocol or the I2C protocol to perform signal switching, so as to adapt to the common PWM signal-controlled fan;
the signal control process of the slave device fans comprises:
Step S201: enabling the slave device fans to recognize each other based on the UART protocol or the I2C protocol, and automatically generating an address code;
automatically numbering the fan connected to the master controller as a first slave device fan and numbering the fan connected to the first slave device fan as a second slave device fan to cascade four fans by analogy or set the fans as required; and
Step S202: setting an MCU for each said slave device fan to realize communication with the master controller, setting input ports and output ports through which all the cascaded slave device fans receive instructions from the master controller and send relevant data back to the master controller, and sending, by the master controller, data to the PC App to be processed;
each said slave device fan is recognized and controlled as an individual specifically through the following steps:
independently setting and controlling rotational speeds and data reading of the four cascaded fans in each group, as well as effects of the light-emitting modules, wherein the light effects of the light-emitting modules are set to be in different colors separately;
providing all data to the master controller based on the UART protocol or the I2C protocol, and then sending the data to the PC App to be managed based on a USB protocol, wherein all control instructions are sent to the controller by the PC App and are then transmitted to the slave device fans.
